(19) United States
(12) Patent Application Publication
(10) Pub. No.: US 2023/0017305 A1
(43) Pub. Date: Jan. 19, 2023

(54) WELL RING FOR RESISTIVE GROUND POWER DOMAIN SEGREGATION

(71) Applicant: Micron Technology, Inc., Boise, ID (US)

(72) Inventors: Mattia Cichocki, Rome (IT); Vladimir Mikhalev, Boise, ID (US); Phani Bharadwaj Vanguri, Boise, ID (US); James Eric Davis, Meridian, ID (US); Kenneth William Marr, Boise, ID (US); Chiara Cerafogli, Boise, ID (US); Michael James Irwin, Boise, ID (US); Domenico Tuzi, Balsorano (IT); Umberto Siciliani, Rubano (IT); Alessandro Alilla, L'Aquila (IT); Andrea Giovanni Xotta, Cornedo Vicentino (IT); Chung-Ping Wu, Cupertino, CA (US); Luigi Marchese, Albignasego (IT); Pasquale Conenna, Rieti (IT); Joonwoo Nam, Cupertino, CA (US); Ishani Bhatt, Sunnyvale, CA (US); Fulvio Rori, Biose, ID (US); Andrea D'Alessandro, Avezzano (IT); Michele Piccardi, Cupertino, CA (US); Aleksey Prozapas, Kuna, ID (US); Luigi Pilolli, L'Aquila (IT); Violante Moschiano, Avezzano (IT)

(21) Appl. No.: 17/730,325

(22) Filed: Apr. 27, 2022

Related U.S. Application Data
(60) Provisional application No. 63/221,795, filed on Jul. 14, 2021.

(51) Int. Cl. H01L 27/02; H01L 27/11519; H01L 27/11524; H01L 27/11529; H01L 27/11556; H01L 27/11565; H01L 27/1157; H01L 27/11573; H01L 27/11582

(52) U.S. Cl. CPC H01L 27/0207; H01L 27/11519; H01L 27/11524; H01L 27/11529; H01L 27/11556; H01L 27/11565; H01L 27/1157; H01L 27/11573; H01L 27/11582; G11C 5/145

(57) ABSTRACT

A variety of applications can include apparatus or methods that provide a well ring for resistive ground power domain segregation. The well ring can be implemented as a n-well in a p-type substrate. Resistive separation between ground domains can be generated by biasing a n-well ring to an external supply voltage. This approach can provide a procedure, from a process standpoint, that provides relatively high flexibility to design for chip floor planning and simulation, while providing sufficient noise rejection between independent ground power domains when correctly sized. Significant noise rejection between ground power domains can be attained.

### PRIORITY APPLICATION

This application claims the benefit of priority to U.S. Provisional Application Ser. No. 63/221,795 filed 14 Jul. 2021, which is incorporated herein by reference in its entirety.

### FIELD OF THE DISCLOSURE

Embodiments of the disclosure relate generally to memory devices and fabrication of memory devices, and more specifically, to a three-dimensional memory structure having resistive segregation of ground power domains.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. A 3D X-Point memory is a non-volatile memory (NVM) technology with a stackable cross-grid data access array in which bit storage is based on a change of bulk resistance.

Flash memory is utilized as non-volatile memory for a wide range of electronic applications. Flash memory devices typically include one or more groups of one-transistor, floating gate or charge trap memory cells that allow for high memory densities, high reliability, and low power consumption. Two common types of flash memory array architectures include NAND and NOR architectures, named after the logic form in which the basic memory cell configuration of each is arranged. The memory cells of the memory array are typically arranged in a matrix. In an example, the gates of each floating gate memory cell in a row of the array are coupled to an access line (e.g., a word line). In a NOR architecture, the drains of each memory cell in a column of the array are coupled to a data line (e.g., a bit line). In a NAND architecture, the drains of each memory cell in a string of the array are coupled together in series, source to drain, between a source line and a bit line.

Memory arrays are being designed as 3D structures in memory devices to increase memory density. The 3D memory array extends in a horizontal plane along a substrate, which can be designated as a x-y plane, and in a vertical direction, taken as the z direction perpendicular to the x-y plane. Other design considerations can be implemented with the 3D memory arrays such as using a circuit under array (CuA) architecture to enhance reduction of die size or increase utilization of space in a die. CuA refers generally to circuitry located in a memory die under a memory array of the memory die. The CuA can include control logic and sensing circuitry for sensing the programmed data states of memory cells of the memory array. With the control logic and sensing circuitry fabricated below the memory array using semiconductor processing that can include CMOS (Complementary Metal Oxide Semiconductor) processing technology, CuA, in some settings, can be referred to as CMOS under array.

For a 3D NAND memory array, which can include vertical strings of memory cells, using floating gate transistors or charge trap transistors, and connections from bit lines positioned above the 3D NAND, vertical connections extending though the 3D NAND memory array or through memory breaks within the 3D NAND memory array can be used to couple to sensing circuitry and other control logic of the CuA for the memory array. A CuA architecture, which allows for circuits that operate with a 3D memory array to be structured in a space in the substrate below the 3D memory array, provides capabilities for higher densities of memory cells. These capabilities address a desire to limit increases in the area (horizontal plane) of the memory die. For continued increases in memory capacity, other design considerations should be implemented for enhancements to reduce circuit area or limit increases of circuit area in memory die.

### BRIEF DESCRIPTION OF THE DRAWINGS

The drawings, which are not necessarily drawn to scale, illustrate generally, by way of example, but not by way of limitation, various embodiments discussed in the present document.

FIG. 1 is a block diagram illustrating an example integrated circuit having multiple regions, where at least one region has a power characteristic different from the other regions of the integrated circuit, according to various embodiments.

FIG. 2 illustrates a functional block diagram of an example memory device including a memory array and associated circuits in which one or more of the associated circuits can be structured in a n-well ring for resistive ground domain segregation in a manner similar to the integrated circuit of FIG. 1, according to various embodiments.

FIG. 3 is a block diagram of regions of an example memory device having a three-dimensional memory array in a circuit under array architecture, according to various embodiments.

FIG. 4 is a representation of an example three-dimensional NAND memory device having a three-dimensional memory array with a circuit under array architecture, according to various embodiments.

FIG. 5A shows an example of four planes of a memory integrated circuit having a pump circuit that can be segregated with respect to a ground for the pump circuit by a n-well ring surrounding the pump circuit, according to various embodiments.

FIG. 5B illustrates a top view of a representation of the pump circuit surrounded by n-well in FIG. 5A, according to various embodiments.

FIG. 5C is a cross-sectional view of FIG. 5B along A-A′, according to various embodiments.

FIG. 6 illustrates a plane of a circuit under an array region of a memory die with an arrangement of page buffer circuits along with datapath circuits in a static page buffer, according to various embodiments.

FIG. 7 shows a plane view of circuits under the array region of the memory die of FIG. 6 with two decoupled metal grids at different metal layers in the circuit under array region, according to various embodiments.

FIG. 8 illustrates substrate areas for segregation of data path circuits, bandgap circuits, and pumps circuits from each other and from other circuits (under global domain) for a memory array of a memory die, according to various embodiments, according to various embodiments.

FIG. 9A illustrates a top view of a circuit surrounded by a n-well ring, according to various embodiments.

FIG. 9B illustrates a cross-sectional view of the circuit surrounded by the n-well ring of FIG. 9A, according to various embodiments.

FIG. 10 shows an example of a n-well, having a width, disposed in two layers in a substrate and above a third layer of the substrate situated with respect to a shallow trench isolation, according to various embodiments.

FIG. 11 illustrates resistances associated with an isolated region in a chip, where the isolated region can be disposed surrounded by a n-well ring, according to various embodiments.

FIG. 12 is a flow diagram of an example method of forming an integrated circuit having well isolation for one or more circuits, according to various embodiments.

FIG. 13 is a block diagram illustrating an example of a machine upon which one or more embodiments may be implemented, according to various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The various embodiments are not necessarily mutually exclusive, as some embodiments can be combined with one or more other embodiments to form new embodiments. The following detailed description is, therefore, not to be taken in a limiting sense.

In a CuA architecture for a memory die having a 3D memory array, the CuA region can include circuits for controlling the operation of the 3D memory array. One or more control circuits of the CuA can provide control signals to the 3D memory array in order to perform a read operation or a write operation on the 3D memory array. The CuA can include one or more of control circuitry, state machines, decoders, sense amplifiers, read/write circuits, and controllers. These circuits can implement one or more memory array operations including erasing, programming, or reading operations. For example, the CuA region can include an on-chip memory controller for determining row and column address, word line and bit line addresses, memory array enable signals, and data latching signals. The operations on the 3D memory array are typically performed to access one or more memory cells in response to requests from other circuits on the memory die or a device external to the memory die. The CuA region can include pad structures to couple the memory array or one or more circuits in the CuA region to other portions of the die of the memory device, or to couple to devices external to the memory device.

Various memory device formats can be structured in a CuA architecture, such as but not limited to NOR or NAND architecture semiconductor memory arrays. Both NOR and NAND flash architecture semiconductor memory arrays are accessed through decoders that activate specific memory cells by selecting the word line coupled to their gates. In a NOR architecture semiconductor memory array, once activated, the selected memory cells place their data values on bit lines, causing different currents to flow depending on the state at which a particular cell is programmed. In a NAND architecture semiconductor memory array, a high bias voltage is applied to a drain-side select gate (SGD) line. Word lines coupled to the gates of the unselected memory cells of each group are driven at a specified pass voltage (e.g., Vpass) to operate the unselected memory cells of each group as pass transistors (e.g., to pass current in a manner unrestricted by their stored data values). Current then flows from the source line to the bit line through each series-coupled group, restricted only by the selected memory cells of each group, placing current encoded data values of selected memory cells on the bit lines.

Each flash memory cell in a NOR or NAND architecture semiconductor memory array can be programmed individually or collectively to one or a number of programmed states. For example, a single-level cell (SLC) can represent one of two programmed states (e.g., 1 or 0), representing one bit of data. Flash memory cells can also represent more than two programmed states, allowing the manufacture of higher density memories without increasing the number of memory cells, as each cell can represent more than one binary digit (e.g., more than one bit). Such cells can be referred to as multi-state memory cells, multi-digit cells, or multi-level cells (MLCs). In certain examples, MLC can refer to a memory cell that can store two bits of data per cell (e.g., one of four programmed states), a triple-level cell (TLC) can refer to a memory cell that can store three bits of data per cell (e.g., one of eight programmed states), and a quad-level cell (QLC) can store four bits of data per cell. MLC is used herein in its broader context, to refer to any memory cell(s) that can store more than one bit of data per cell (i.e., that can represent more than two programmed states). The sensing and control circuitry for such NOR or NAND architecture semiconductor memory arrays can be structured beneath the respective memory array in a CuA architecture.

An electronic device implemented as an integrated circuit (IC), also called a chip, on a common substrate can include multiple circuits configured in different power domains for the integrated circuit. Power rails for each domain may also be shared among the multiple circuits, where the multiple circuits have heterogeneous headroom specifications and noise specifications. Heterogeneous headroom and noise specifications for the integrated circuit can lead to inefficiencies. Headroom is typically taken as defining a minimal amount of input voltage necessary in order for the circuit to operate properly. Headroom can be a supply minimum value (maximum IR drop, where IR is the product of current through a resistance R) minus a ground maximum bounce happening at the same time as the maximum IR drop. Noise can mainly be related to ground (GND) with the noise measured as peak-to-peak noise. Headroom and noise concerns for a NAND CuA architecture can occur, where critical circuits are allocated below the memory array and in most cases far away from respective power supplies or pads to connect to power. In addition, even if circuits are served by different power domains, these circuits share the same GND, which can be a fundamental concern in determining headroom and noise.

The overall sizing, which can be defined by total metal and capacitance allocated, for an on-die power-delivery-network (PDN) to be effective, can be determined as function of total current absorbed and maximum IR-drop permitted to allow circuits to work properly. The function can be a directly-proportional relationship. A main inefficiency in this approach is that total current is determined by a worst case injection by all circuits operating together, while maximum IR-drop is determined to allow a single circuit to work properly, where the single circuit is more sensitive to noise and headroom. PDN sharing becomes ineffective when the single most sensitive circuit does not correspond to the circuit or group of circuits injecting a significant part of the total current on the same PDN, with the single most sensitive circuit determined based on maximum IR-drop.

An example of this inefficiency in a NAND memory die is demonstrated by page buffer circuits and datapath circuits in a plane that share power supply VCC and GND. With respect to these circuits, the page buffer circuits are the greatest source of current injection and the datapath circuits are the most restrictive in terms of headroom. Another example are pump circuits, which inject relatively high current and noise onto GND but can easily withstand smaller headroom and higher noise levels compared to most of the sensitive circuits in the rest of the chip. A main complexity for segregating GND is caused by the fact that the entire chip shares the same substrate.

In various embodiments, a well ring can be implemented to resistively decouple circuits at the substrate level. A well ring is a ring that surrounds a specified region but is not directly below the specified region. For example, a well ring can surround a specific circuit of an integrated circuit having multiple circuits. The well ring can be coupled to a connection to be operatively biased to an external supply voltage. The use of the well ring structure can provide an inexpensive approach, in terms of process and layout area, to resistively decouple the circuits. The decoupling provides an isolation for the circuits that can segregate circuits into different domains of the chip. With an n-well ring in a p-substrate used to isolate a circuit, the n-well can be biased at an external supply voltage VCCx. For a chip using a n-substrate, a p-well can be used to isolate a circuit. The use of a n-well in a p-type substrate can aid in significantly reducing to almost eliminating, to within several percent, noise injection and IR drops/bounces (impacting headroom) between different power domains through a common ground.

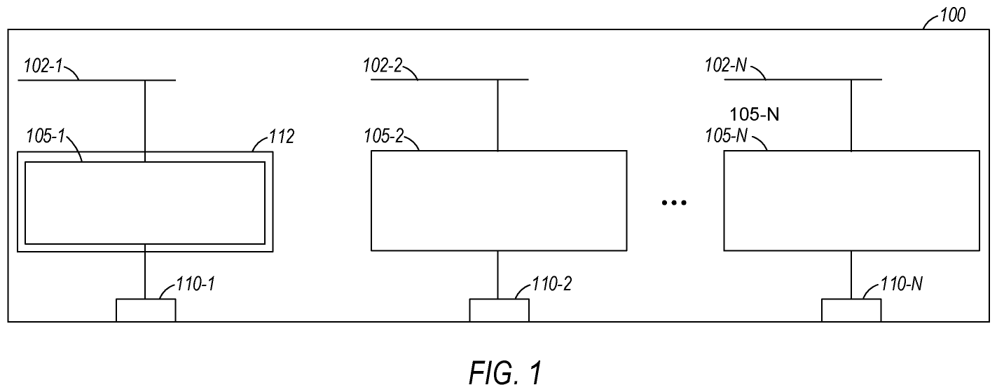

FIG. 1 is a block diagram illustrating an embodiment of an example integrated circuit 100 having multiple regions 105-1, 105-2 . . . 105-N where at least one region, such as region 105-1, has a power characteristic different from the other regions 105-2 . . . 105-N of the integrated circuit 100. A well ring 112 provides isolation to the first region 105-1 with the well ring 112 surrounding the first region 105-1, resistively segregating the first region 105-1 from the second region 105-2, for example. The well ring 112 is a well of a first conductivity type in a substrate of a second conductivity type different from the first conductivity type. The well ring 112 can be a n-well ring in a p-substrate.

The use of a well ring provides a mechanism to address noise injection between different power domains through ground. The well ring can impart resistive isolation that can provide rejection of the noise on ground that can occur from one voltage supply to another. The well ring can be placed around a specific area for which segregation is desired. The resistance between one side of the well ring to the other side can include dependence on the resistance below the specific area and the well ring. With the well ring biased to a supply voltage to generate a non-negligible depletion region below the specific area and the well ring, a significantly high resistance can be generated.

The first region 105-1 can include a circuit, where the circuit can be connected to a power rail 102-1 and a ground node 110-1. The second region 105-2 can include a circuit, where the circuit of the second region 105-2 can be connected to a power rail 102-2 and a ground node 110-2. Other regions, such as region 105-N, can include a circuit coupled to power rail such as power rail 102-N and a ground node 110-N. The power rail 102-1 can be different from power rails 102-2 . . . 102-N such that first region 105-1 is part of a first power domain different from power domains associated with power rails 102-2 . . . 102-N. In various embodiments, power rails 102-2 . . . 102-N can be a common power rail defining a second power domain different from the first power domain with power rails 102-2 . . . 102-N arranged as part of a global ground node.

The first region 105-1 and the well ring 112 can be disposed in the integrated circuit 100 such that a region of the integrated circuit 100 below the first region 105-1 has a resistance of magnitude sufficiently large to decouple a resistive path to the ground node 110-1 of the first region 105-1 from a resistive path to a global ground node of the integrated circuit 100, where the global ground node is outside the first region 105-1. The well ring 112 can have a structure including a doping concentration to inhibit crosstalk noise between a first power-delivery-network of the first region 105-1 and a second power-delivery-network of the second region 105-2. The power rail 102-1 can be designed for a PDN with the power rails 102-2 . . . 102-N designed for another PDN. With the segegration of region 105-1 provided by a well ring 112, the design of these PDNs can be conducted with an analysis that can attempt to optimize metal allocation for these PDNs.

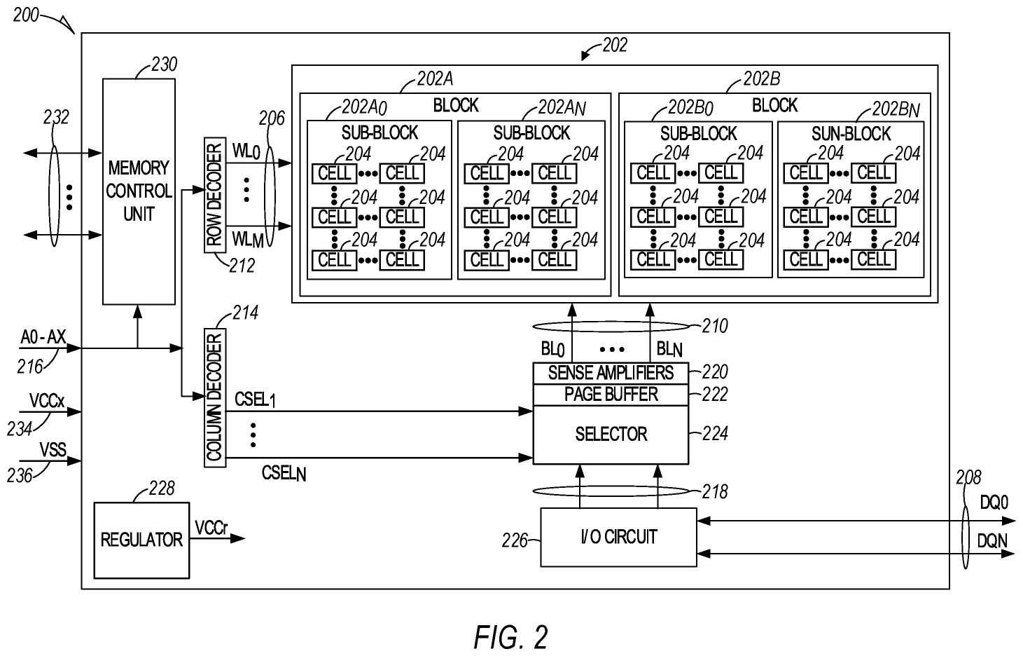

FIG. 2 illustrates a functional block diagram of an example memory device 200 including a memory array 202 and associated circuits. One or more circuits of the associated circuits can be structured in a n-well ring for resistive ground domain segregation in a manner discussed with respect to the integrated circuit 100 of FIG. 1. Example memory device 200 includes a plurality of memory cells 204, and one or more circuits or components to provide communication with, or perform one or more memory operations on, the memory array 202. The memory device 200 can include a row decoder 212, a column decoder 214, sense amplifiers 220, a page buffer 222, a selector 224, an I/O circuit 226, and a memory control unit 230. In various embodiments, the memory device 200 can be structured with a CuA architecture. Control circuitry for the memory array 202 can be located in a CuA region below the memory array 202 in the CuA architecture.

The memory cells 204 of the memory array 202 can be arranged in blocks, such as first and second blocks 202A, 202B. Each block can include sub-blocks. For example, the first block 202A can include first and second sub-blocks 202A₀, 202Aₙ, and the second block 202B can include first and second sub-blocks 202B₀, 202Bₙ. Each sub-block can include a number of physical pages, with each page including a number of memory cells 204. Although illustrated herein as having two blocks, with each block having two sub-blocks, and each sub-block having a number of memory cells 204, in other examples, the memory array 202 can include more or fewer blocks, sub-blocks, memory cells, etc. In other examples, the memory cells 204 can be arranged in a number of rows, columns, pages, sub-blocks, blocks, etc., and accessed using, for example, access lines 206, first data lines 210, or one or more select gates, source lines, etc.

The memory control unit 230 can control memory operations of the memory device 200 according to one or more signals or instructions received on control lines 232, including, for example, one or more clock signals or control signals that indicate a desired operation (e.g., write, read, erase, etc.), or address signals (A0-AX) received on one or more address lines 216. One or more devices external to the memory device 200 can control the values of the control signals on the control lines 232 or the address signals on the address line 216. Examples of devices external to the memory device 200 can include, but are not limited to, a host, a memory controller, a processor, or one or more circuits or components not illustrated in FIG. 2.

The memory device 200 can use access lines 206 and first data lines 210 to transfer data to (e.g., write or erase) or from (e.g., read) one or more of the memory cells 204. The row decoder 212 and the column decoder 214 can receive and decode the address signals (A0-AX) from the address line 216, can determine which of the memory cells 204 are to be accessed, and can provide signals to one or more of the access lines 206 (e.g., one or more of a plurality of word lines (WL0-WLm)) or the first data lines 210 (e.g., one or more of a plurality of bit lines (BL0-BLn)), such as described above.

The memory device 200 can include sense circuitry, such as the sense amplifiers 220, configured to determine the values of data on (e.g., read), or to determine the values of data to be written to, the memory cells 204 using the first data lines 210. For example, in a selected string of memory cells 204, one or more of the sense amplifiers 220 can read a logic level in the selected memory cell 204 in response to a read current flowing in the memory array 202 through the selected string to the data lines 210.

One or more devices external to the memory device 200 can communicate with the memory device 200 using the I/O lines (DQ0-DQN) 208, address lines 216 (A0-AX), or control lines 232. The I/O circuit 226 can transfer values of data in or out of the memory device 200, such as in or out of the page buffer 222 or the memory array 202, using the I/O lines 208, according to, for example, the control lines 232 and address lines 216. The page buffer 222 can store data received from the one or more devices external to the memory device 200 before the data is programmed into relevant portions of the memory array 202, or can store data read from the memory array 202 before the data is transmitted to the one or more devices external to the memory device 200.

The column decoder 214 can receive and decode address signals (A0-AX) into one or more column select signals (CSEL1-CSELn). The selector 224 (e.g., a select circuit) can receive the column select signals (CSEL1-CSELn) and select data in the page buffer 222 representing values of data to be read from or to be programmed into memory cells 204. Selected data can be transferred between the page buffer 222 and the I/O circuit 226 using second data lines 218. The memory control unit 230 can receive positive and negative supply signals, such as a supply voltage (VCCx) 234 and a negative supply (VSS) 236 (e.g., a ground potential), from an external source or supply (e.g., an internal or external battery, an AC-to-DC converter, etc.). In certain examples, the memory control unit 230 can include a regulator 228 to internally provide positive or negative supply signals.

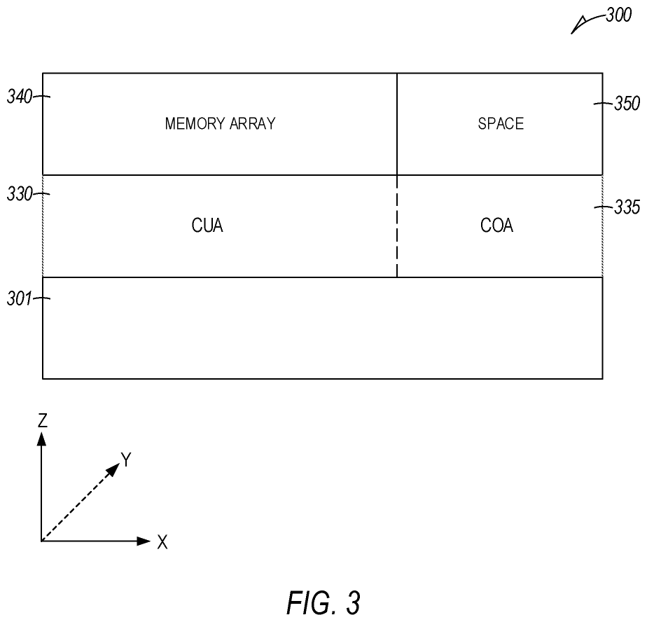

FIG. 3 is a block diagram of regions of an embodiment of an example memory device 300 having a 3D memory array, in which the regions are shown in the z-x plane. A memory array region 340 having horizontal planes (x-y) of memory cells is disposed vertically over a CuA region 330 disposed in a substrate 301. The horizontal planes (x-y) of memory cells can be structured as multiple arranged tiers comprising memory cells. The CuA region 330 includes control circuitry for the memory array of the memory array region 340. The control circuitry in the CuA region 330 can be implemented with one or more circuits structured in a n-well ring for resistive ground domain segregation in a manner similar to the integrated circuit 100 of FIG. 1. The control circuitry can include one or more instrumentalities similar to row decoder 212, column decoder 214, sense amplifiers 220, page buffer 222, selector 224, I/O circuit 226, and memory control unit 230 of memory device 200 shown in FIG. 2. A space 350 is adjacent the memory array region 340 and above the CuA region 330. The space 350 can be implemented beyond the horizontal extent of the memory array and may not directly contain elements of the control and sensing circuitry for the memory array, which can be located in the CuA region 330. The CuA region 330 can include a space of the CuA located directly below the 3D memory array of memory array region 340 such that this space of the CuA extends at least in one direction in the x-y plane to the same extent as the 3D memory array extends in this direction. The CuA region 330 can include a region in the die outside of the horizontal extent of the 3D memory array, referred to as OA, and below a level of the 3D memory array. In various embodiments, circuits or contacts can be structured outside the horizontal extent of and below a level of the 3D memory array. The circuits in this OA region can be referred to as circuits outside array, CoA, in a CoA region 335. The space of the CoA can be disposed adjacent the portion of the space of the CuA region 330 that contains control circuitry for the memory array of the memory array region 340 and below the level of the 3D memory array.

With the memory device 300 having a CoA region 335 adjacent the CuA region 330 containing control circuitry for the memory array, and placed below a level of the memory array in memory array region 340, the space 350 can be arranged directly over the CoA region 335. The CoA region 335 can include pads to couple to nodes for external connections or pins of the package for the memory device 300. The space 350 can also be implemented with conductive columns to couple to the top levels of the memory device 300.

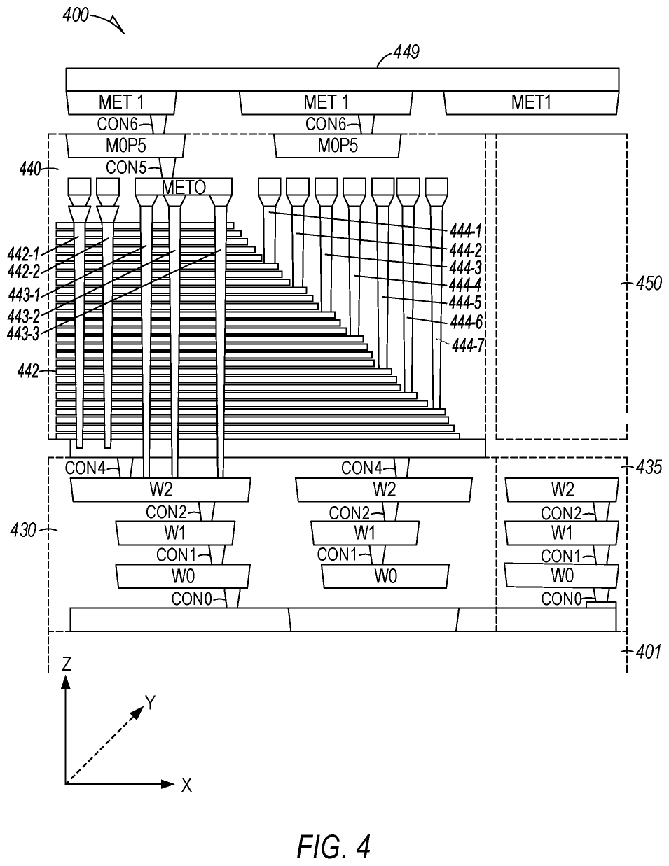

FIG. 4 is a representation of an embodiment of an example 3D NAND memory device 400 having a 3D memory array, in which the regions are shown in a vertical cross-section in the z-x plane. A memory array region 440 having horizontal planes (x-y) of memory cells is disposed vertically over a CuA region 430 disposed in a substrate 401. The horizontal planes (x-y) of memory cells are structured as multiple arranged tiers 442 comprising memory cells. The CuA region 430 includes control circuitry for the memory array of the memory array region 440. The control circuitry in the CuA region 430 can be implemented with one or more circuits structured in a n-well ring for resistive ground domain segregation in a manner similar to the integrated circuit 100 of FIG. 1. The control circuitry can include one or more instrumentalities similar to row decoder 212, column decoder 214, sense amplifiers 220, page buffer 222, selector 224, I/O circuit 226, and memory control unit 230 of memory device 200 of FIG. 2 or other circuits to control access to selected memory cells of the tiers 442. A space 450, similar to the space 350 of FIG. 3, is adjacent the memory array region 440 and above the CuA region 430. The 3D NAND memory device 400 can have a CoA region 435, as part of the CuA region 430, adjacent the section of the CuA region 430 containing the control circuitry and sensing of the the memory array in memory array region 440, and below a level of the memory array in memory array region 440. The space 450 can be arranged directly over the CoA region 435. The CoA region 435 can include pads to couple to nodes for external connections or pins of the package for the memory device 400. The space 450 can also be implemented with conductive columns to couple to the top levels of the memory device 400.

FIG. 4 also illustrates some of the elements of a NAND memory device having a 3D memory array. For discussion purposes, a small number of structural elements are shown in FIG. 4. Memory cells of the tiers 442 can extend from pillars such as pillars 442-1 and 442-2. Though only two such pillars are shown, other such pillars are located with respect to the tiers 442. The 3D NAND memory device 400 can also include, but is not limited in number to, conductive contact vias 443-1, 443-2, and 443-3 along with conductive plugs 444-1 . . . 444-7. The pillars 442-1 and 442-2, the conductive contact vias 443-1, 443-2, and 443-3, and the conductive plugs 444-1 . . . 444-7 can extend above and below tiers 442 and can contact different metallization levels, which can be at various vertical locations in the structure of the 3D memory array of the memory array region 440, such that access to the memory cells in the tiers 442 can be attained by a device external to the 3D memory array. The pillars 442-1 and 442-2, the conductive contact vias 443-1, 443-2, and 443-3, and the conductive plugs 444-1 . . . 444-7, and other similar structures provide vertical connections extending though the 3D memory array or through memory breaks within the 3D memory array, which vertical connections can be used to couple to sensing circuitry and other control logic of the CuA region 430 for the 3D memory array.

As a non-limiting example, FIG. 4 shows two metal layers labelled W2, two metal layers labelled W1, and two metal layers labelled W0 in the CuA region 430, where these metal layers provide electrical coupling with circuit elements in the CuA region 430. In some embodiments, metal layers may be replaced with conductively doped semiconductor material, such as but not limited to conductively doped polysilicon. Electrical connections between metal layers or conductive semiconductor layers at different vertical levels in the CuA region 430 can be provided by conductive contact vias labelled CON0, CON1, CON2, and CON4. Similarly, the CoA region 435 can include metal layer labelled W2, two metal layers labelled W1, and two metal layers labelled W0 to provide electrical coupling with circuit elements in the CoA region 435.

At the top of the memory region 440 are metal layers labelled MOPS, which metal layers can interface with a number of metallization layers labelled MET1. MET1 can be top metallizations for the die containing the 3D NAND memory device 400 and can be covered by a passivation layer 449. The passivation layer 449 is an electrically insulating layer and can include one or more materials such as, but not limited to, tetraethyl orthosilicate (TEOS) and an oxynitride. The oxynitride, for example, can include silicon oxynitride. The various MOPS layers can couple to various MET1 layers by different contact vias CON6 and can couple to the conductive contact vias 443-1, 443-2, and 443-3 in the memory array region 440.

The conductive contact vias 443-1, 443-2, and 443-3, which are conductive vias in the memory array region 440, can be long conductive vias, relative to the conductive contact vias CON0, CON1, CON2, CON4, CON5, and CON6. The conductive contact vias 443-1, 443-2, and 443-3 can couple to metal layers W2 in the CuA region 430. Other such relatively long structures such as the conductive contact vias 443-1, 443-2, and 443-3, which can be referred to as CON3 metal, can also terminate in a different metal layer MET0.

In a memory chip, such as but not limited to a 3D NAND memory die with a CuA architecture, pumps circuits can be localized in specific regions of the chip. These pump circuits can inject a relatively high current onto GND. Current injection on GND for a PDN from pump circuits can cause peak-to-peak noises of the order of 200 mV and can affect sensing in page buffer circuits, which can be sensitive to a few tens of mV. This can especially affect an intermediate word line (iWL) architecture, where in this architecture, when a plane is performing a sensing operation, another plane can be in a pump phase, which can be noisy.

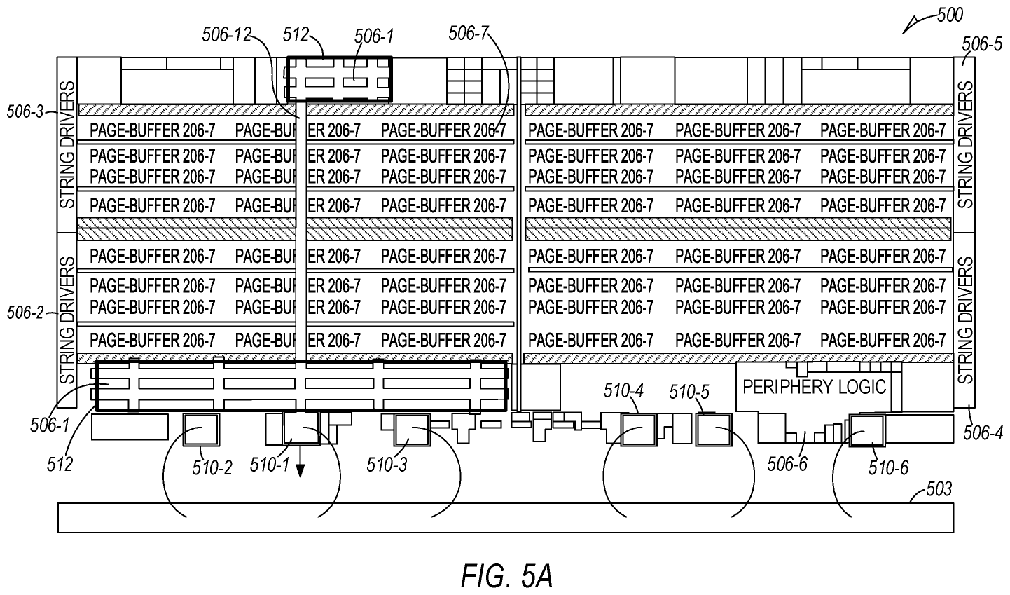

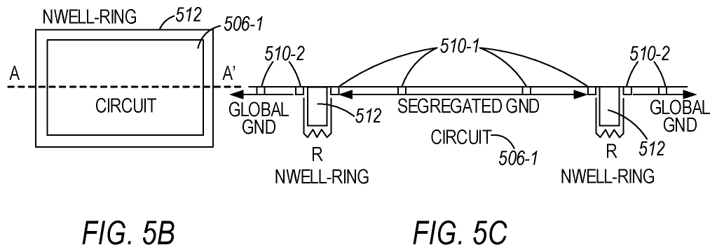

FIG. 5A shows an embodiment of four planes of a memory integrated circuit 500 having a pump circuit 506-1 that can be segregated with respect to a GND 510-1 for the pump circuit 506-1 by a n-well ring 512 surrounding the pump circuit 506-1. The pump circuit 506-1 can be implemented in multiple regions with a PDN metal bus 506-12 connecting the multiple regions. The PDN metal bus 506-12 is provided by metals above the substrate. The plane of the memory integrated circuit 500 can also include a number of different circuits including, but not limited to, string drivers 506-2, 506-3, 506-4, and 506-5, a number of page buffers 506-7, and periphery logic 506-6. The string drivers 506-2, 506-3, 506-4, and 506-5, a number of page buffers 506-7, and periphery logic 506-6 can be on a different power domain than the pump circuit 506-1 and can use the GNDs 510-2, 510-3, 510-4, 510-5, and 510-6, which can be coupled to a global GND.

By segregating pumps circuits 506-1 from the other circuits, both on the substrate of the memory integrated circuit 500 and through the specific PDN metal bus 506-12 coming from the dedicated pad 510-1, cross noise between GND 510-1 and the GNDs 510-2, 510-3, 510-4, 510-5, and 510-6 can be substantially reduced or completely canceled out. This segregation can also have a positive headroom impact. In addition, having the dedicated pad 510-1 can also enable further segregation for the domains at a package level 503.

Simulations were performed to determine parameters for the structure of FIG. 5A to meet a target noise rejection from GND 510-1 for the pump circuit 506-1 relative to a common ground. FIG. 5B illustrates a top view of a representation of the pump circuit 506-1 surrounded by n-well 512 of FIG. 5A. FIG. 5C is a cross-sectional view of FIG. 5C along A-A′. The resistance to be considered is only the one resistance below the nwell ring 512, since the p-type substrate is contacted immediately on the two sides of the n-well ring 512 to the two gnd domains using p-taps 510-1 that are p-tap connections for segregated GND and p-taps 510-2 that are p-tap connections for global GND. A p-tap is a p+ shallow diffusion to create ohmic connection between metal and substrate. A total perimeter for the pump circuit 506-1 around which to dispose a n-well ring was set to approximately 15,000 μm. The target was set at greater than 95% rejection from pump GND (GND 510-1) to common GND at a 150 mV pump GND (GND 510-1) with a bounce less than 10 mV maximum noise on the common GND. The GND metal PDN resistance was taken to be three ohms and the pump GND (GND 510-1) was taken to be three ohms. For the sum of of noise rejection to meet the target using a n-well ring of a width of approximately 0.8 μm, acceptable sheet resistance below the n-well was determined to be greater than the range of one to two mega-ohms/sq. For the sum of of noise rejection to meet the target using a n-well ring of a width of approximately 2.4 μm, acceptable sheet resistance below the n-well was determined to be greater than the range of one-fourth to one-half of a mega-ohm. For the sum of of noise rejection to meet the target using a n-well ring of a width of approximately 4.8 μm, acceptable sheet resistance below the n-well was determined to be greater than the range of one-eighth to one-fourth of a mega-ohm. Simulations can provide the design parameters for the width of the n-well, doping of the n-well, and selection of target noise rejection.

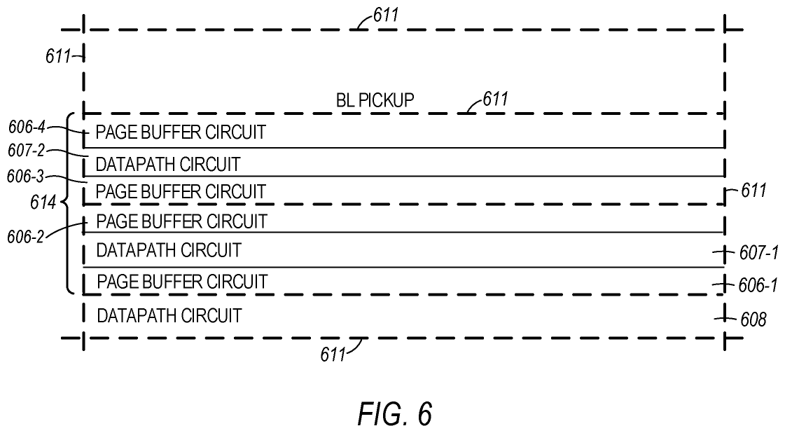

In various embodiments, GND segregation can be structured for page buffer circuits and datapath circuits in a plane of a CuA region of a memory die such as CuA region 330 of FIG. 3 and CuA region 430 of FIG. 4. FIG. 6 illustrates a plane of a CuA region of a memory die with an arrangement of page buffer circuits 606-1, 606-2, 606-3, and 606-4 along with datapath circuits 607-1 and 607-2 in a static page buffer (SPB) 614. The page buffer circuits 606-1, 606-2, 606-3, and 606-4 can have, for example, a minimum VCC headroom greater than 1.5 V, while the datapath circuits 607-1 and 607-2 can have, for example, a minimum VCC headroom greater than 1.9 V with a GND bounce higher than 100 mV being critical. The plane of the CuA region can also include a datapath circuit 608 having a minimum VCCLO headroom greater than 1V and a minimum VCC headroom greater than 1.9 V with a GND bounce higher than 100 mV being critical. The plane of the CuA region can also have a data line (BL) pickup 616 and pickups 611. The BL pickup 616 and pickups 611 are discontinuities in the array (pillars/vertical strings) to allow passages from above array metal layers to CuA metal layers.

Datapath headroom can be more stringent compared to page buffer headroom in terms of maximum allowed GND bounce or VCC/VCCLO headroom. Most of the current is injected by page buffer circuits. GND segregation can enable creation of two decoupled metal grids at different metal layers in the CuA region and the substrate of the memory die, where one metal grid is structured for datapath circuits and the other one is structured for page buffer circuits. The segregation can be used to optimize PDN sizing in the CuA region (also for top level, above array, metals optimization can be performed) and substrate for each of the datapath circuits and buffer circuits independently and more effectively. Designing towards optimized sizing can result in allocating less metal for the PDNs, which can allow for increased compaction providing more physical room for signal paths and other components relevant for the memory integrated circuit.

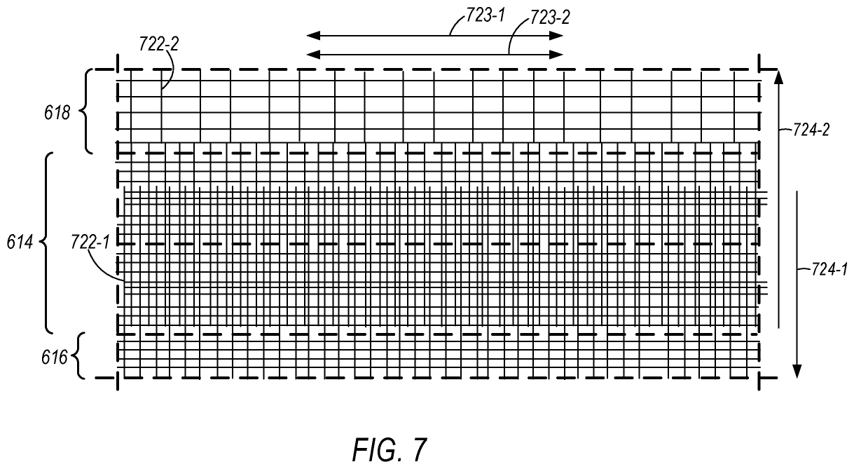

FIG. 7 shows the plane of the CuA region of the memory die of FIG. 6 with two decoupled metal grids 722-1 and 722-2 at different metal layers in the CuA region. The metal grid 722-1 is structured for the datapath circuits 607-1 and 607-2 of FIG. 6 in the SPB 614 and datapath circuits 608 of FIG. 6. The SPB 614 can include primary data caches (PDCs) and secondary data caches (SDCs). The metal grid 722-2 is structured for the page buffer circuits 606-1, 606-2, 606-3, and 606-4 of FIG. 6 in the SPB 614. The metal grid 722-1 is connected horizontally along the bi-direction 723-1 and the metal grid 722-2 is connected horizontally along the bi-direction 723-2. The metal grid 722-1 is connected only toward the pickup 616 along direction 724-1 and the metal grid 722-2 is connected only toward pickup 618 along direction 724-2.

Simulations were performed to determine parameters to meet a target noise rejection from a ground for a SPB relative to a common ground. A total perimeter for the SPB around which to dispose a n-well ring was set to approximately 25,000 μm. The target was set at greater than 95% rejection from GND for a PDC to GND for a SDC at a 150 mV on PDC GND with a bounce less than 10 mV noise on the SDC GND. The PDC GND metal PDN resistance was taken to be four ohms and the SDC/datapath GND was taken to be four ohms. For the sum of noise rejection to meet the target using a n-well ring of a width of approximately 0.8 μm, acceptable sheet resistance below the n-well was determined to be greater than the range of three to four mega-ohms. For the sum of noise rejection to meet the target using a n-well ring of a width of approximately 2.4 μm, acceptable sheet resistance below the n-well was determined to be greater than the range of one to two mega-ohm. For the sum of noise rejection to meet the target using a n-well ring of a width of approximately 4.8 μm, acceptable sheet resistance below the n-well was determined to be greater than the range of one-half to one mega-ohm. For a feature size of approximately 0.8 to reduce impact on pitch area, the simulations indicate a tolerance of approximately 90% rejection.

In various embodiments, GND segregation can be structured for the full levels of a CuA region for a number of different circuits. The different circuits can include page buffer circuits, datapath circuits, bandgap circuits and other circuits that can use GND segregation. GND segregation can be scaled from segregation at a metal grid plane in the CuA region to a full chip extending segregation through all metal levels up to pads of the memory die.

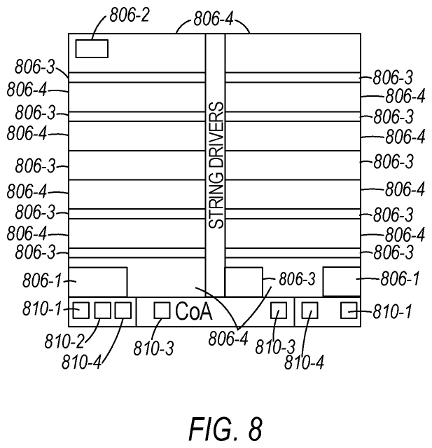

FIG. 8 illustrates substrate areas for segregation of data path circuits, bandgap, pumps circuits from each other and from other circuits for a memory die. All substrate areas 806-3 for datapath circuits share the same PDN delivered from VSSQ pad 810-4. All substrate areas 806-2 for bandgap circuits share the same PDN delivered from reference ground (Gnd_REF) pad 810-2. All substrate areas 806-1 for pump circuits share the same PDN delivered from GND_PMP pads 810-1. In FIG. 8, four PDNs can be identified, including a global PDN serving substrate areas 806-4 and delivered from GND pads 810-4, a PDN for datapaths delivered from GND areas 810-3, a PDN for pumps delivered from GND areas 810-1, and a PDN delivered from analog reference GND areas 810-2.

Simulations were performed to determine parameters to meet a target noise rejection from a ground for a bandgap circuit relative to a common ground. A total perimeter for the bandgap circuit around which to dispose a n-well ring was set to approximately 1,200 μm. The target was set at greater than 97% rejection from common GND to reference GND for the bandgap circuit at a 150 mV GND with a bounce less than 5 mV noise on the reference GND. The GND resistance was taken to be three ohms and the reference GND was taken to be fifty ohms. The GND metal PDN resistance was taken to be three ohms and the reference GND metal PDN was taken to be fifty ohms. For the sum of of noise rejection to meet the target using a n-well ring of a width of approximately 0.8 μm, acceptable sheet resistance below the n-well was determined to be greater than the range of two to three mega-ohms. For the sum of of noise rejection to meet the target using a n-well ring of a width of approximately 2.4 μm, acceptable sheet resistance below the n-well was determined to be greater than the range of one-half to one mega-ohm. For the sum of of noise rejection to meet the target using a n-well ring of a width of approximately 4.8 μm, acceptable sheet resistance below the n-well was determined to be greater than the range of one-fourth to one-half mega-ohm.

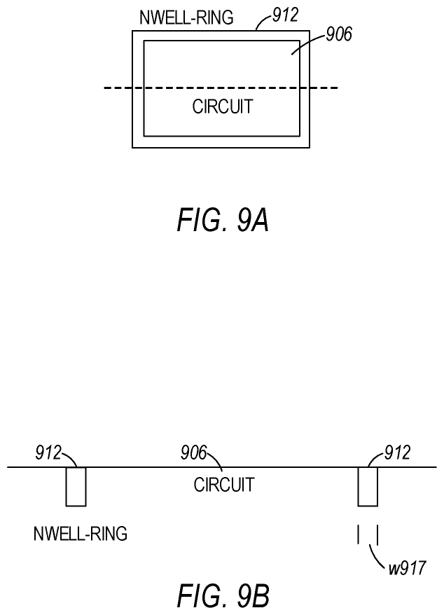

FIG. 9A illustrates a top view of a circuit 906 surrounded by a n-well ring 912. FIG. 9B illustrates a cross-sectional view of the circuit 906 surrounded by the n-well ring 912 of FIG. 9A. The n-well ring 912 has a width (w) 917. The shape of the n-well ring 912 is not limited to a rectangular shape, but can be a shape that surrounds the circuit 906 according to the layout of the circuit 906 or parameters of the n-well ring 912 to provide a specified resistance for resistive ground power domain segregation. The n-well ring 912 surrounds the circuit 906 without the circuit 906 being structured in a n-well, that is, without the n-well ring 912 being disposed directly below the circuit 906.

In various embodiments, circuit isolation can be attained by a n-well ring providing substrate resistive segregation. In order to provide substrate segregation to a significant amount of noise, the n-well ring can be biased to an external supply (VCCx) during operation. The n-well ring can be coupled to pad to receive the supply voltage from a source external to the memory chip. Biasing the n-well to a voltage that increases the depletion region vertically below the n-well ring can significantly increase the resistance under the n-well ring.

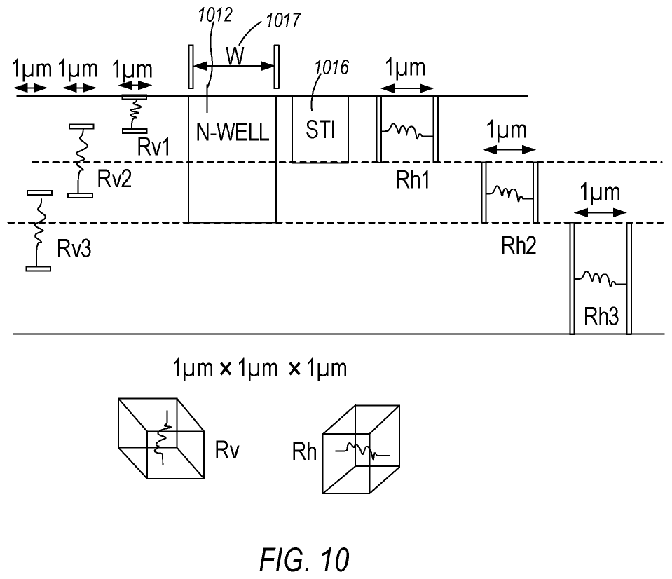

FIG. 10 shows an example of a n-well 1012, having a width 1017, disposed in two layers in a substrate and above a third layer of the substrate situated with respect to a shallow trench isolation (STI) 1016. A vertical resistance can be defined for a 1 μm×1 μm×1 μm volume in each layer. The two layers in which the n-well is disposed have vertical resistances Rᵥ₁ and Rᵥ₂, with the third layer that is below the n-well having a vertical resistance Rᵥ₃. A horizontal resistance can be defined for a 1 μm×1 μm×1 μm volume in each layer. The two layers in which the n-well is disposed have horizontal resistances Rh1 and Rh2, with the third layer that is below the n-well having a horizontal resistance Rh3. Materials for the three layers and the n-well, including doping of the n-well, can be selected such that the horizontal resistance Rh3 of the p-type substrate below the n-well is greater than 1 MΩ/sq. This resistance can be further increased when the n-well is biased to VCCx because of the increase of the depletion layer underneath the n-well in the substructure. The parameters to achieve this resistance can be selected from applying simulation procedures such as, but not limited to, technology computer-aided design (TCAD) simulations. Simulations can be performed taking into consideration structures other than STI 1016.

The n-well ring can resistively isolate the p-type substrate for the area surrounded by the n-well from the p-type substrate outside the n-well. The n-well can be fabricated using conventional processing techniques for forming n-well-like structures for other applications such as for n-wells in which device components are structured. Modifications can be made to provide enhancement to the sheet resistance to increase the sheet resistance below the n-well, for example by approximately +30%. A width of the n-well ring can be selected to meet specifications for the die in which the substrate resistive segregation is being implemented. In an example implementation, the minimum width of the n-well ring can be less than approximately one μm, making it suitable for inserting the n-well ring in pitch areas with a negligible area impact.

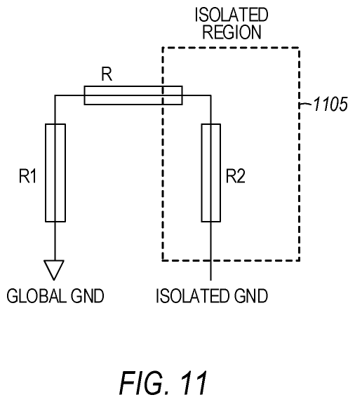

Effective noise rejection can be attained using n-well rings for isolation providing substrate segregation. FIG. 11 illustrates resistances associated with isolated region 1105 in a chip, where the isolated region 1105 can be disposed surrounded by a n-well ring. The isolated region 1105 can be arranged with a resistance R that is an isolation resistance to pass underneath the isolation n-well for the entire perimeter of the isolated region 1105. The chip can have a global GND pad with an associated resistance R1 of a PDN path to the global GND pad. The isolated region 1105 can be coupled to a dedicated pad as an isolated GND pad for a PDN path from the isolated region 1105. Effective noise rejection can be provided with R being much greater than R1 of the PDN path to a global GND pad and with R being much greater than R2 of the PDN path to the isolated GND: R>>R1 and R>>R2.

In a non-limiting example, consider a pump circuit having a perimeter of approximately 15,000 μm. An isolation n-well ring of approximately 2.5 μm width all around the given pump circuit can provide for R being approximately 160Ω. For a global GND domain with R1 of approximately 3Ω and an isolated GND domain with R2 of approximately 3Ω resistance toward their respective pads, the noise rejection can be greater than 2%, i.e., only approximately 2% of the total current from the pump circuit is injected into the global GND.

The use of well rings can provide a mechanism to significantly reduce ground noise injection. A well ring for GND segregation, as taught herein, can reduce almost to 0 (only few % such as within approximately 5%) cross noise injection between sensitive domains, such as headroom sensitive domains and current hungry domains. The well ring isolation can be used with a circuit without changing the components of the circuit or models of the circuits. Designing for well rings for GND segregation can decouple full chip (FC) simulations for datapath domains, page buffer domains, and pumps domains. Simulations of n-well rings for circuits in a substrate can provide the design parameters for the width of the n-well, the doping of the n-well, and selection of target noise rejection.

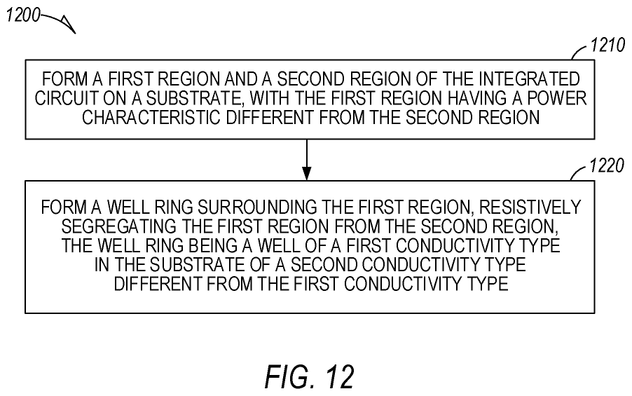

FIG. 12 is a flow diagram of an embodiment of an example method 1200 of forming an integrated circuit. At 1210, a first region and a second region are formed for the integrated circuit on a substrate. For the integrated circuit, the first region has a power characteristic different from the second region. At 1220, a well ring is formed surrounding the first region, resistively segregating the first region from the second region. The well ring is a well below which the substrate has a conductivity value different from the conductivity value it has without the well. With respect to FIG. 10, Rh1 and Rh2 is much smaller than Rh3.

Variations of the method 1200 or methods similar to the method 1200 can include a number of different embodiments that may be combined depending on the application of such methods or the architecture or process flow for which such methods are implemented. Such methods can include coupling the well ring to a pad of the integrated circuit with the pad structured to connect the integrated circuit to a supply voltage external to the integrated circuit. Variations can include forming a first power-delivery-network for the first region; forming a second power-delivery-network for the second region; and forming the well ring as a n-well ring in a p-type substrate. The formation of the n-well ring can provide substrate resistive segregation of the first power-delivery-network from the second power-delivery-network.

In various embodiments, an integrated circuit can comprise a first region having a power characteristic different from a second region of the integrated circuit; and a well ring providing isolation to the first region with the well ring surrounding the first region, resistively segregating the first region from the second region. The well ring is a well below which the substrate has a conductivity value different from the conductivity value it has without the well. With respect to FIG. 10, Rh1 and Rh2 is much smaller than Rh3.

Variations of such an integrated circuit or similar an integrated circuits can include a number of different embodiments that may be combined depending on the application of such integrated circuits or the architecture of devices or systems in which such integrated circuits are implemented. Such variations can include the first region having a first circuit in a first power domain and the second region having a second circuit in a second power domain, with the first power domain being different from the second power domain. Variations can include the first region and the well ring being disposed in the integrated circuit such that a region of the integrated circuit below the first region has a resistance of magnitude sufficiently large to decouple a resistive path to a ground node of the first region from a resistive path to a global ground node of the integrated circuit. The global ground node is outside the first region. The well ring can have a structure including a doping concentration to inhibit crosstalk noise between a first power-delivery-network of the first region and a second power-delivery-network of the second region.

In various embodiments, an integrated circuit can comprise multiple circuits including a circuit in a first power domain of the integrated circuit different from a second power domain of the integrated circuit; and a n-well ring surrounding the circuit, the n-well ring structured to generate resistive separation between the first power domain and the second power domain.

Variations of such an integrated circuit or similar an integrated circuits can include a number of different embodiments that may be combined depending on the application of such integrated circuits or the architecture of devices or systems in which such integrated circuits are implemented. Such variations can include the circuit having a resistive path to a ground node of the integrated circuit, with the ground node dedicated to the first power domain and the ground node being different from a global ground node of the integrated circuit. Variations can include the circuit having a resistive path to a ground node of the integrated circuit, with the ground node dedicated to the circuit and the ground node being different from a global ground node of the integrated circuit.

Variations of such an integrated circuit or similar an integrated circuits can include the circuit and the n-well ring disposed in the integrated circuit such that a region of the integrated circuit below the circuit has a resistance of magnitude sufficiently large to decouple a resistive path to a ground node to the circuit from a resistive path to a global ground node of the integrated circuit. Variations can include the integrated circuit having a pad to connect to an external supply voltage, with the n-well ring coupled to the pad to operatively bias the n-well ring to the external supply voltage. The n-well ring can have a structure including a doping concentration to inhibit crosstalk noise between a power-delivery-network to the circuit in the first power domain and a power-delivery-network in the second power domain.

In various embodiments, a memory device can comprise a memory array extending above a substrate, where the memory array includes multiple tiers comprising memory cells; a region below the memory array, where the region includes control circuitry for the memory array; multiple circuits in the region below the memory array, where the multiple circuits include a circuit in a first power domain different from a second power domain; and an n-well ring surrounding the circuit, where the n-well ring is structured to resistively segregate the circuit from the second power domain in the substrate.

Variations of such a memory device or similar memory device can include a number of different embodiments that may be combined depending on the application of such a memory devices or the architecture of devices or systems in which such memory devices are implemented. Such variations can include the circuit having a resistive path to a ground node of the memory device, with the ground node dedicated to the circuit and the ground node being different from a global ground node of the memory device. Such variations can include the circuit and the n-well ring disposed in the memory device such that a region of the memory device below the circuit has a resistance of magnitude sufficiently large to decouple the resistive path to the ground node from a resistive path to the global ground node. Variations can include a pad to connect to an external supply voltage, with the n-well ring coupled to the pad to operatively bias the n-well ring to the external supply voltage.

Variations of such a memory device or similar memory device can include the n-well ring having a structure including a doping concentration to inhibit crosstalk noise between a power-delivery-network to the circuit in the first power domain and a power-delivery-network in the second power domain. The circuit can be a pump circuit. The memory device can include a page buffer circuit in the second power domain with the circuit in the first power domain being a datapath circuit. The memory device can include three or more circuits with each of the three or more circuits being in a different power domain with the three or more circuits circuit segregated at a substrate level by different n-well rings.

Electronic devices, such as mobile electronic devices (e.g., smart phones, tablets, etc.), electronic devices for use in automotive applications (e.g., automotive sensors, control units, driver-assistance systems, passenger safety or comfort systems, etc.), and Internet-connected appliances or devices (e.g., Internet-of-Things (IoT) devices, etc.), have varying storage needs depending on, among other things, the type of electronic device, use environment, performance expectations, etc.

Electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, an SSD, an MMC, or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc.

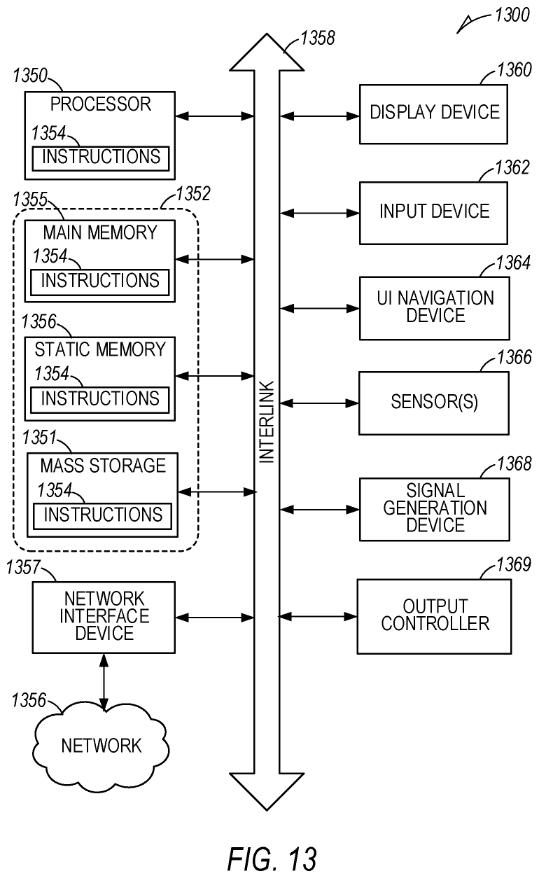

FIG. 13 illustrates a block diagram of an example machine 1300 having one or more memory devices having a CuA architecture. Such memories can include a memory array extending over a substrate, with the memory array including multiple vertically arranged tiers comprising memory cells. The machine 1300, having one or more such memory devices, may operate as a standalone machine or may be connected, for example networked, to other machines.

In a networked deployment, the machine 1300 may operate in the capacity of a server machine, a client machine, or both in server-client network environments. In an example, the machine 1300 may act as a peer machine in peer-to-peer (P2P) (or other distributed) network environment. The machine 1300 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations. The example machine 1300 can be arranged to operate with one or more integrated circuits having one or more well rings for resistive ground power domain segregation. The example machine 1300 can be arranged to operate with one or more memory devices having a CuA architecture such as but not limited to the example memory device 300 of FIG. 3. The example machine 1300 can include one or more memory devices having structures as discussed with respect to the memory device 200 of FIG. 2, the memory device 300 of FIG. 3, the memory device 400 of FIG. 4, and elements of FIGS. 5-8.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine (e.g., computer system) 1300 may include a hardware processor 1350 (e.g., a CPU, a GPU, a hardware processor core, or any combination thereof), a main memory 1355, and a static memory 1356, some or all of which may communicate with each other via an interlink (e.g., bus) 1258. The machine 1300 may further include a display device 1360, an alphanumeric input device 1362 (e.g., a keyboard), and a user interface (UI) navigation device 1364 (e.g., a mouse). In an example, the display device 1360, input device 1362, and UI navigation device 1364 may be a touch screen display. The machine 1300 may additionally include a mass storage device (e.g., drive unit) 1351, a signal generation device 1368 (e.g., a speaker), a signal generation device 1368, and one or more sensors 1366, such as a global positioning system (GPS) sensor, compass, accelerometer, or other sensor. The machine 1300 may include an output controller 1368, such as a serial (e.g., USB, parallel, or other wired or wireless (e.g., infrared (IR), near field communication (NFC), etc.) connection to communicate or control one or more peripheral devices (e.g., a printer, card reader, etc.).

The machine 1300 may include a machine-readable medium 1352 on which is stored one or more sets of data structures or instructions 1354 (e.g., software) embodying or utilized by the machine 1300 to perform any one or more of the techniques or functions for which the machine 1300 is designed. The instructions 1354 may also reside, completely or at least partially, within the main memory 1355, within static memory 1356, or within the hardware processor 1350 during execution thereof by the machine 1300. In an example, one or any combination of the hardware processor 1350, the main memory 1355, the static memory 1356, or the mass storage device 1351 may constitute the machine-readable medium 1352.

While the machine-readable medium 1352 is illustrated as a single medium, the term “machine-readable medium” may include a single medium or multiple media (e.g., a centralized or distributed database, or associated caches and servers) configured to store the one or more instructions 1354. The term “machine-readable medium” may include any medium that is capable of storing, encoding, or carrying instructions for execution by the machine 1300 and that cause the machine 1300 to perform any one or more of the techniques to which the machine 1300 is designed, or that is capable of storing, encoding or carrying data structures used by or associated with such instructions. Non-limiting machine-readable medium examples may include solid-state memories, and optical and magnetic media. In an example, a massed machine-readable medium comprises a machine-readable medium with a plurality of particles having invariant (e.g., rest) mass. Accordingly, massed machine-readable media are not transitory propagating signals. Specific examples of massed machine-readable media may include: non-volatile memory, such as semiconductor memory devices (e.g., EPROM, EEPROM) and flash memory devices; magnetic disks, such as internal hard disks and removable disks; magneto-optical disks; and compact disc-ROM (CD-ROM) and digital versatile disc-read only memory (DVD-ROM) disks.

The instructions 1354 (e.g., software, programs, an operating system (OS), etc.) or other data are stored on the mass storage device 1351, can be accessed by the main memory 1355 for use by the processor 1350. The main memory 1355 (e.g., DRAM) is typically fast, but volatile, and thus a different type of storage than the mass storage device 1351 (e.g., an SSD), which is suitable for long-term storage, including while in an “off” condition. The instructions 1354 or data in use by a user or the machine 1300 are typically loaded in the main memory 1355 for use by the processor 1350. When the main memory 1355 is full, virtual space from the mass storage device 1351 can be allocated to supplement the main memory 1355; however, because the mass storage device 1351 is typically slower than the main memory 1355, and write speeds are typically at least twice as slow as read speeds, use of virtual memory can greatly reduce user experience due to storage device latency (in contrast to the main memory 1355, e.g., DRAM). Further, use of the mass storage device 1351 for virtual memory can greatly reduce the usable lifespan of the mass storage device 1351.

In contrast to virtual memory, virtual memory compression (e.g., the Linux® kernel feature “ZRAM”) uses part of the memory as compressed block storage to avoid paging to the mass storage device 1351. Paging takes place in the compressed block until it is necessary to write such data to the mass storage device 1351. Virtual memory compression increases the usable size of main memory 1355, while reducing wear on the mass storage device 1351.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, embedded MMC (eMMC™) devices are attached to a circuit board and considered a component of the host device, with read speeds that rival Serial Advanced Technology Attachment (SATA)-based SSD devices. However, demand for mobile device performance continues to increase, such as to fully enable virtual or augmented-reality devices, utilize increasing networks speeds, etc. In response to this demand, storage devices have shifted from parallel to serial communication interfaces. Universal Flash Storage (UFS) devices, including controllers and firmware, communicate with a host device using a low-voltage differential signaling (LVDS) serial interface with dedicated read/write paths, further advancing greater read/write speeds.

The instructions 1354 may further be transmitted or received over a communications network 1356 using a transmission medium via the signal generation device 1368 utilizing any one of a number of transfer protocols (e.g., frame relay, Internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the signal generation device 1368 may include one or more physical jacks (e.g., Ethernet, coaxial, or phone jacks) or one or more antennas to connect to the communications network 1356. In an example, the signal generation device 1368 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of carrying instructions to and for execution by the machine 1300, and includes instrumentalities to propagate digital or analog communications signals to facilitate communication of such instructions, which instructions may be implemented by software.

The following are example embodiments of devices and methods, in accordance with the teachings herein.

An example integrated circuit 1 can comprise: a first region having a power characteristic different from a second region of the integrated circuit; and a well ring providing isolation to the first region with the well ring surrounding the first region, resistively segregating the first region from the second region, the well ring being a well below which a substrate has a conductivity value different from the conductivity value that the substrate has without the well.

An example integrated circuit 2 can include features of example integrated circuit 1 and can include the first region to include a first circuit in a first power domain and the second region includes a second circuit in a second power domain, with the first power domain being different from the second power domain.

An example integrated circuit 3 can include features of any of the preceding example integrated circuits and can include the first region and the well ring disposed in the integrated circuit such that a region of the integrated circuit below the first region has a resistance of magnitude sufficiently large to decouple a resistive path to a ground node of the first region from a resistive path to a global ground node of the integrated circuit, the global ground node being outside the first region.

An example integrated circuit 4 can include features of any of the preceding example integrated circuits and can include the well ring having a structure including a doping concentration to inhibit crosstalk noise between a first power-delivery-network of the first region and a second power-delivery-network of the second region.

In an example integrated circuit 5, any of the integrated circuits of example integrated circuits 1 to 4 may include integrated circuits incorporated into an electronic memory apparatus further comprising a host processor and a communication bus extending between the host processor and the integrated circuit.

In an example integrated circuit 6, any of the integrated circuits of example integrated circuits 1 to 5 may be modified to include any structure presented in another of example integrated circuits 1 to 5.

In an example integrated circuit 7, any apparatus associated with the integrated circuits of example integrated circuits 1 to 6 may further include a machine-readable storage device configured to store instructions as a physical state, wherein the instructions may be used to perform one or more operations of the apparatus.

In an example integrated circuit 8, any of the integrated circuits of example integrated circuits 1 to 7 may be formed in accordance with any of the methods of the below example methods 1 to 3.

An example integrated circuit can 9 comprise: multiple circuits including a circuit in a first power domain of the integrated circuit different from a second power domain of the integrated circuit; and a n-well ring surrounding the circuit, the n-well ring structured to generate resistive separation between the first power domain and the second power domain.

An example integrated circuit 10 can include features of example integrated circuit 9 and can include the circuit including a resistive path to a ground node of the integrated circuit, with the ground node dedicated to the first power domain and the ground node being different from a global ground node of the integrated circuit.

An example integrated circuit 11 can include features of any of the preceding example integrated circuits 9 to 10 and can include the circuit including a resistive path to a ground node of the integrated circuit, with the ground node dedicated to the circuit and the ground node being different from a global ground node of the integrated circuit.

An example integrated circuit 12 can include features of any of the preceding example integrated circuits 9 to 11 and can include the circuit and the n-well ring disposed in the integrated circuit such that a region of the integrated circuit below the circuit has a resistance of magnitude sufficiently large to decouple a resistive path to a ground node to the circuit from a resistive path to a global ground node of the integrated circuit.

An example integrated circuit 13 can include features of any of the preceding example integrated circuits 9 to 12 and can include a pad to connect to an external supply voltage, with the n-well ring coupled to the pad to operatively bias the n-well ring to the external supply voltage.

An example integrated circuit 14 can include features of any of the preceding example integrated circuits 9 to 13 and can include the n-well ring having a structure including a doping concentration to inhibit crosstalk noise between a power-delivery-network to the circuit in the first power domain and a power-delivery-network in the second power domain.

In an example integrated circuit 15, any of the integrated circuits of example integrated circuits 9 to 14 may include integrated circuits incorporated into an electronic memory apparatus further comprising a host processor and a communication bus extending between the host processor and the integrated circuit.

In an example integrated circuit 16, any of the integrated circuits of example integrated circuits 9 to 15 may be modified to include any structure presented in another of example integrated circuit 9-15.

In an example integrated circuit 17, any apparatus associated with the integrated circuits of example integrated circuits 9 to 16 may further include a machine-readable storage device configured to store instructions as a physical state, wherein the instructions may be used to perform one or more operations of the apparatus.

In an example integrated circuit 18, any of the integrated circuits of example integrated circuits 9 to 17 may be formed in accordance with any of the methods of the below example methods 1 to 3.

An example memory device 1 can comprise: a memory array extending above a substrate, the memory array including multiple tiers comprising memory cells; a region below the memory array, the region including control circuitry for the memory array; multiple circuits in the region below the memory array, the multiple circuits including a circuit in a first power domain different from a second power domain; and a n-well ring surrounding the circuit, the n-well ring structured to resistively segregate the circuit from the second power domain in the substrate.

An example memory device 2 can include features of example memory device 1 and can include the circuit including a resistive path to a ground node of the memory device, with the ground node dedicated to the circuit and the ground node being different from a global ground node of the memory device.

An example memory device 3 can include features of any of the preceding example memory devices and can include the circuit and the n-well ring disposed in the memory device such that a region of the memory device below the circuit has a resistance of magnitude sufficiently large to decouple the resistive path to the ground node from a resistive path to the global ground node.

An example memory device 4 can include features of any of the preceding example memory devices and can include a pad to connect to an external supply voltage, with the n-well ring coupled to the pad to operatively bias the n-well ring to the external supply voltage.

An example memory device 5 can include features of any of the preceding example memory devices and can include the n-well ring having a structure including a doping concentration to inhibit crosstalk noise between a power-delivery-network to the circuit in the first power domain and a power-delivery-network in the second power domain.

An example memory device 6 can include features of any of the preceding example memory devices and can include the circuit being a pump circuit.

An example memory device 7 can include features of any of the preceding example memory devices and can include a page buffer circuit in the second power domain with the circuit in the first power domain being a datapath circuit.

An example memory device 8 can include features of any of the preceding example memory devices and can include three or more circuits with each of the three or more circuits being in a different power domain with the three or more circuits circuit segregated at a substrate level by different n-well rings.

In an example memory device 9, any of the memory devices of example memory devices 1 to 8 may include memory devices incorporated into an electronic memory apparatus further comprising a host processor and a communication bus extending between the host processor and the memory device.

In an example memory device 10, any of the memory devices of example memory devices 1 to 9 may be modified to include any structure presented in another of example memory device 1-9.

In an example memory device 11, any apparatus associated with the memory devices of example memory devices 1 to 10 may further include a machine-readable storage device configured to store instructions as a physical state, wherein the instructions may be used to perform one or more operations of the apparatus.

In an example memory device 12, any of the memory devices of example memory devices 1 to 11 may be formed in accordance with any of the methods of the following example methods 1 to 3.

An example method 1 of forming an integrated circuit can comprise: forming a first region and a second region of the integrated circuit on a substrate, with the first region having a power characteristic different from the second region; and forming a well ring surrounding the first region, resistively segregating the first region from the second region, the well ring being a well of a first conductivity type in the substrate of a second conductivity type different from the first conductivity type.

An example method 2 of forming an integrated circuit can include features of example method 1 of forming an integrated circuit and can include coupling the well ring to a pad of the integrated circuit with the pad structured to connect the integrated circuit to a supply voltage external to the integrated circuit.

An example method 3 of forming an integrated circuit can include features of example method 2 of forming an integrated circuit and can include forming a first power-delivery-network for the first region; forming a second power-delivery-network for the second region; and forming the well ring as a n-well ring in a p-type substrate, with the formation of the n-well ring to provide substrate resistive segregation of the first power-delivery-network from the second power-delivery-network.

In an example method 4 of forming an integrated circuit, any of the example methods 1 to 3 of forming an integrated circuit may be performed in forming an electronic associated with a memory device.

In an example method 5 of forming an integrated circuit, any of the example methods 1 to 4 of forming an integrated circuit may be modified to include operations set forth in any other of method examples 1 to 4 of forming an integrated circuit.

In an example method 6 of forming an integrated circuit, any of the example methods 1 to 5 of forming an integrated circuit may be implemented at least in part through use of instructions stored as a physical state in one or more machine-readable storage devices.

An example method 7 of forming an integrated circuit can include features of any of the preceding example methods 1 to 6 of forming an integrated circuit and can include performing functions associated with any features of example integrated circuits 1 to 18 and example memory devices 1 to 12.

An example machine-readable storage device 1 storing instructions that, when executed by one or more processors, cause a machine to perform operations, can comprise instructions to perform functions associated with any features of example integrated circuits 1 to 18 and example memory devices 1 to 12 or perform methods associated with any features of example methods 1 to 7.

A well ring, such as a n-well in a p-type substrate, can be implemented for GND segregation with approximately zero cost in terms of chip area used and complexity of processes used to design and fabricate the well ring. A well ring for GND segregation can allow significant customization of on-die PDN sizing. A well ring for GND segregation, as taught herein, can reduce almost to 0 (only few %) cross noise injection between sensitive domains, such as headroom sensitive domains and current hungry domains. Designing for well rings for GND segregation can decouple FC simulations for datapath domains, page buffer domains, and pumps domains.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. The above description is intended to be illustrative, and not restrictive, and that the phraseology or terminology employed herein is for the purpose of description. In addition, in the foregoing Detailed Description, it can be seen that various features are grouped together in a single embodiment for the purpose of streamlining the disclosure. Combinations of the above embodiments and other embodiments will be apparent to those of skill in the art upon studying the above description.

What is claimed is:

1. An integrated circuit comprising:
a first region having a power characteristic different from a second region of the integrated circuit;
a well ring providing isolation to the first region with the well ring surrounding the first region, resistively segregating the first region from the second region, the well ring being a well below which a substrate has a conductivity value different from the conductivity value that the substrate has without the well.

2. The integrated circuit of claim 1, wherein the first region includes a first circuit in a first power domain and the second region includes a second circuit in a second power domain, with the first power domain being different from the second power domain.

3. The integrated circuit of claim 1, wherein the first region and the well ring are disposed in the integrated circuit such that a region of the integrated circuit below the first region has a resistance of magnitude sufficiently large to decouple a resistive path to a ground node of the first region from a resistive path to a global ground node of the integrated circuit, the global ground node being outside the first region.

4. The integrated circuit of claim 1, wherein the well ring has a structure including a doping concentration to inhibit crosstalk noise between a first power-delivery-network of the first region and a second power-delivery-network of the second region.

5. An integrated circuit comprising:
multiple circuits including a circuit in a first power domain of the integrated circuit different from a second power domain of the integrated circuit;
a n-well ring surrounding the circuit, the n-well ring structured to generate resistive separation between the first power domain and the second power domain.

6. The integrated circuit of claim 5, wherein the circuit includes a resistive path to a ground node of the integrated circuit, with the ground node dedicated to the first power domain and the ground node being different from a global ground node of the integrated circuit.

7. The integrated circuit of claim 5, wherein the circuit includes a resistive path to a ground node of the integrated circuit, with the ground node dedicated to the circuit and the ground node being different from a global ground node of the integrated circuit.

8. The integrated circuit of claim 5, wherein the circuit and the n-well ring are disposed in the integrated circuit such that a region of the integrated circuit below the circuit has a resistance of magnitude sufficiently large to decouple a resistive path to a ground node to the circuit from a resistive path to a global ground node of the integrated circuit.

9. The integrated circuit of claim 5, wherein the integrated circuit includes a pad to connect to an external supply voltage, with the n-well ring coupled to the pad to operatively bias the n-well ring to the external supply voltage.

10. The integrated circuit of claim 5, wherein the n-well ring has a structure including a doping concentration to inhibit crosstalk noise between a power-delivery-network to the circuit in the first power domain and a power-delivery-network in the second power domain.

11. A memory device comprising:
a memory array extending above a substrate, the memory array including multiple tiers comprising memory cells;
a region below the memory array, the region including control circuitry for the memory array;
multiple circuits in the region below the memory array, the multiple circuits including a circuit in a first power domain different from a second power domain; and
a n-well ring surrounding the circuit, the n-well ring structured to resistively segregate the circuit from the second power domain in the substrate.

12. The memory device of claim 11, wherein the circuit includes a resistive path to a ground node of the memory device, with the ground node dedicated to the circuit and the ground node being different from a global ground node of the memory device.

13. The memory device of claim 12, wherein the circuit and the n-well ring are disposed in the memory device such that a region of the memory device below the circuit has a resistance of magnitude sufficiently large to decouple the resistive path to the ground node from a resistive path to the global ground node.

14. The memory device of claim 11, wherein the memory device includes a pad to connect to an external supply voltage, with the n-well ring coupled to the pad to operatively bias the n-well ring to the external supply voltage.

15. The memory device of claim 11, wherein the n-well ring has a structure including a doping concentration to inhibit crosstalk noise between a power-delivery-network to the circuit in the first power domain and a power-delivery-network in the second power domain.

16. The memory device of claim 11, wherein the circuit is a pump circuit.

17. The memory device of claim 11, wherein the memory device includes a page buffer circuit in the second power domain with the circuit in the first power domain being a datapath circuit.

18. The memory device of claim 11, wherein the memory device includes three or more circuits with each of the three or more circuits being in a different power domain with the three or more circuits circuit segregated at a substrate level by different n-well rings.

19. A method of forming an integrated circuit, the method comprising:
forming a first region and a second region of the integrated circuit on a substrate, with the first region having a power characteristic different from the second region; and
forming a well ring surrounding the first region, resistively segregating the first region from the second region, the well ring being a well of a first conductivity type in the substrate of a second conductivity type different from the first conductivity type.

20. The method of claim 19, wherein the method includes coupling the well ring to a pad of the integrated circuit with the pad structured to connect the integrated circuit to a supply voltage external to the integrated circuit.

21. The method of claim 20, wherein the method includes:
forming a first power-delivery-network for the first region;
forming a second power-delivery-network for the second region; and
forming the well ring as a n-well ring in a p-type substrate, with the formation of the n-well ring to provide substrate resistive segregation of the first power-delivery-network from the second power-delivery-network.
